(19) United States
(12) Patent Application Publication
(10) Pub. No.: US 2026/0107481 A1
(43) Pub. Date: Apr. 16, 2026

(54) REDUCING RESISTANCE IN MEMORY SYSTEMS

(71) Applicant: Micron Technology, Inc., Boise, ID (US)

(72) Inventors: Bharat Bhushan, Boise, ID (US); Kunal R. Parekh, Boise, ID (US); Ameen D. Akel, Rancho Cordova, CA (US); Fuad Badrieh, Boise, ID (US); Brent Keeth, Boise, ID (US); Akshay N. Singh, Boise, ID (US)

(21) Appl. No.: 19/354,508

(22) Filed: Oct. 9, 2025

Related U.S. Application Data
(60) Provisional application No. 63/707,723, filed on Oct. 15, 2024.

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

Methods, systems, and devices for reducing resistance in memory systems are described. A first die of a memory device may include multiple first vias, a first metallic pad, and a second metallic pad. A second die of the memory device may include multiple second vias, a third metallic pad, and a first via, where the second vias, the third metallic pad, and the first via. Accordingly, the first die and the second die may be bonded to form a power delivery network for the memory device, where a first end of each via of the first vias is bonded with a first end of a respective via of the second vias, the first metallic pad is bonded with the third metallic pad, and the second metallic pad is bonded with a first end of the first via.

### CROSS REFERENCE

The present Application for Patent claims priority to U.S. Patent Application No. 63/707,723 by Bhushan et al., entitled “REDUCING RESISTANCE IN MEMORY SYSTEMS,” filed Oct. 15, 2024, which is assigned to the assignee hereof, and which is expressly incorporated by reference in its entirety herein.

### TECHNICAL FIELD

The following relates to one or more semiconductor systems, including reducing resistance in memory systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports reducing resistance in memory systems in accordance with examples as disclosed herein.

FIG. 2 shows an example of a device that supports reducing resistance in memory devices in accordance with examples as disclosed herein.

FIG. 3 shows an example of a device that supports reducing resistance in memory devices in accordance with examples as disclosed herein.

FIG. 4 shows an example of a device that supports reducing resistance in memory devices in accordance with examples as disclosed herein.

FIG. 5 shows an example of a device that supports reducing resistance in memory devices in accordance with examples as disclosed herein.

FIG. 6 shows an example of a device that supports reducing resistance in memory devices in accordance with examples as disclosed herein.

FIG. 7 shows an example of a device that supports reducing resistance in memory devices in accordance with examples as disclosed herein.

FIG. 8 shows a flowchart illustrating a method or methods that support reducing resistance in memory systems in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a DRAM system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some cases, the stack of semiconductor dies may include a power delivery network (PDN), which may facilitate the flow of power throughout the stack of memory dies. In such cases, the PDN may include one or more vias (e.g., through silicon vias (TSVs), through oxide vias (TOVs), among other examples) and other circuitry (e.g., metallic signal pads, back end of line (BEOL) circuitry, among other examples) distributed throughout the stack of semiconductor dies, where such vias and circuitry facilitate the transfer of power throughout the semiconductor dies of the stack. In such cases, the vias and components of the PDN may have a resistance (both electrical resistance and/or thermal resistance) based on various parameters of the PDN. That is, as a pitch of the vias (e.g., distance between each via and associated circuitry) within the stack of semiconductor dies decreases, the resistivity (e.g., electrical and/or thermal) of the portions of the stack that include the PDN may increase. In some examples, such increased resistivity may lead to the stack of semiconductor dies being unable to dissipate heat during operation or manufacturing (e.g., in the case of increased thermal resistivity), lead to poor electrical performance during operations (e.g., in the case of increased electrical resistivity), among other examples, which may degrade operations at the stack of semiconductor dies. Thus, techniques may be desired to reduce the resistance of the PDN in the stack of semiconductor dies.

In accordance with the techniques described herein, the stack of semiconductor dies may include various structures of a PDN, each associated with a reduced resistance (e.g., increased thermal conductivity, increased electrical conductivity) relative to other PDN structures. For example, each PDN structure may utilize various combinations of materials to form the vias and other components, where such combinations of materials may reduce the resistance of the PDN. Additionally, one or more semiconductor dies of the stack of semiconductor stack may include additional components that have reduced resistance, thereby reducing the resistivity of the PDN.

In some examples, the stack of semiconductor dies may include a first die (e.g., memory die, including a dynamic random-access memory (DRAM) portion) that includes multiple first vias, a first metallic pad, and a second metallic pad, where such components may be associated with a first portion of the PDN of the stack of semiconductor dies. A second die (e.g., logic die, including a data proximity layer) of the stack of semiconductor dies may include multiple second vias, a third metallic pad, and a single via, where such components may be associated with a second portion of the PDN of the stack of semiconductor dies. In such examples, each of the vias and metallic pads may be formed using copper, which may reduce the thermal resistivity of the PDN, thereby reducing overheating issues. Accordingly, the first die and the second die may be bonded together (e.g., via a hybrid bond), thereby forming the PDN. In such examples, the first die and the second die may be bonded together such that a first end of each of the multiple first vias may be coupled with a first end of a respective via of the multiple second vias, while the first metallic pad of the first die may be bonded with the third metallic pad of the second die and the second metallic pad of the first die may be coupled with a first end of the first via of the second die.

In addition to applicability in memory systems as described herein, techniques for reducing resistance in memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing the resistivity (e.g., thermal and/or electrical) of a PDN of the stack of semiconductor dies, which may reduce overheating within the stack, improve electrical conductivity of the stack, among other benefits.

Features of the disclosure are illustrated and described in the context of systems and architectures. Features of the disclosure are further illustrated and described in the context of flowcharts.

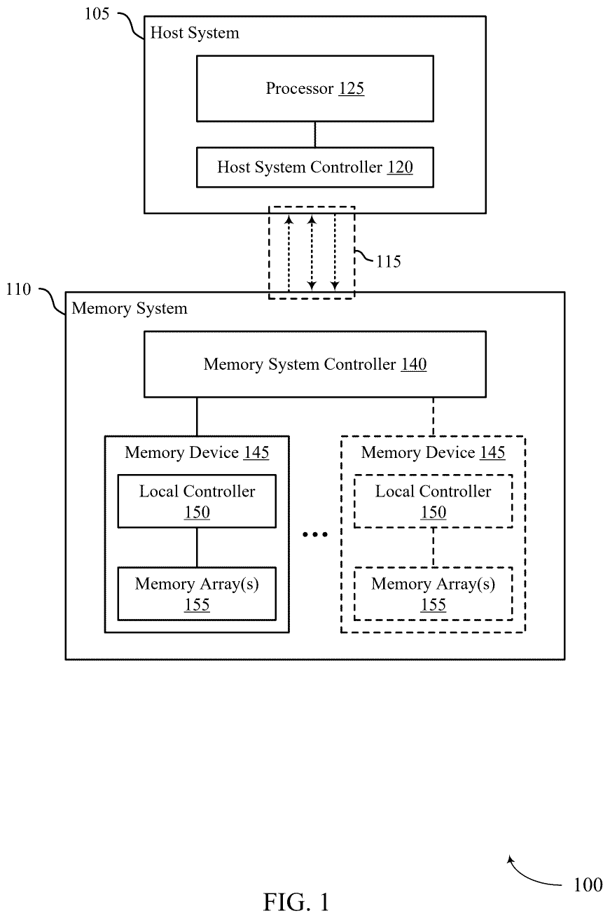

FIG. 1 shows an example of a system 100 that supports reducing resistance in memory systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked DRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some cases, the memory system 110 and host system 105 may be formed across a stack of dies, where the stack of semiconductor dies may include a PDN, which may facilitate the traversal of voltage throughout the stack of dies. In such cases, the PDN may include one or more vias (e.g., TSVs, TOVs, copper vias, among other examples) and other circuitry (e.g., metallic signal pads, BEOL circuitry, among other examples) distributed throughout the stack of dies, where such vias and circuitry facilitate the transfer of voltage (e.g., power) throughout the dies of the stack. In such cases, the vias and components of the PDN may increase the resistance (e.g., thermal and/or electrical) of the stack of dies. That is, as a pitch of the vias (e.g., distance between each via decreases) within the stack of dies decreases, the resistivity of the portions of the stack that include the PDN may increase. Such increased resistivity may lead to the stack of semiconductor dies being unable to dissipate heat during operation or manufacturing (e.g., in the case of increased thermal resistance), lead to reduced electrical performance within the stack of semiconductor dies (e.g., in the case of increased electrical resistance), or both. Thus, techniques may be desired to reduce the resistance of the PDN in the stack of semiconductor dies.

In accordance with the techniques described herein, the stack of semiconductor dies may include various structures of a PDN, each associated with a reduced resistance (e.g., increased thermal and/or electrical conductivity) relative to other PDN structures. For example, each PDN structure may utilize various combinations of materials to form the vias and other components, where such combinations of materials may reduce the resistance of the PDN. Additionally, one or more semiconductor dies of the stack of semiconductor stack may include additional components that have reduced resistance, thereby reducing the resistivity of the PDN.

In some examples, the stack of semiconductor dies may include a first die (e.g., memory die, including DRAM portion) that includes multiple first vias, a first metallic pad, and a second metallic pad, where such components may be associated with a first portion of the PDN of the stack of semiconductor dies. A second die (e.g., logic die, including a data proximity layer) of the stack of semiconductor dies may include multiple second vias, a third metallic pad, and a single via, where such components may be associated with a second portion of the PDN of the stack of semiconductor dies. In such examples, each of the vias and metallic pads may be formed using copper, which may reduce the thermal resistivity of the PDN, thereby reducing overheating issues. Accordingly, the first die and the second die may be bonded together (e.g., via a hybrid bond), thereby forming the PDN. In such examples, the first die and the second die may be bonded together such that a first end of each of the multiple first vias may be coupled with a first end of a respective via of the multiple second vias, while the first metallic pad of the first die may be bonded with the third metallic pad of the second die and the second metallic pad of the first die may be coupled with a first end of the first via of the second die.

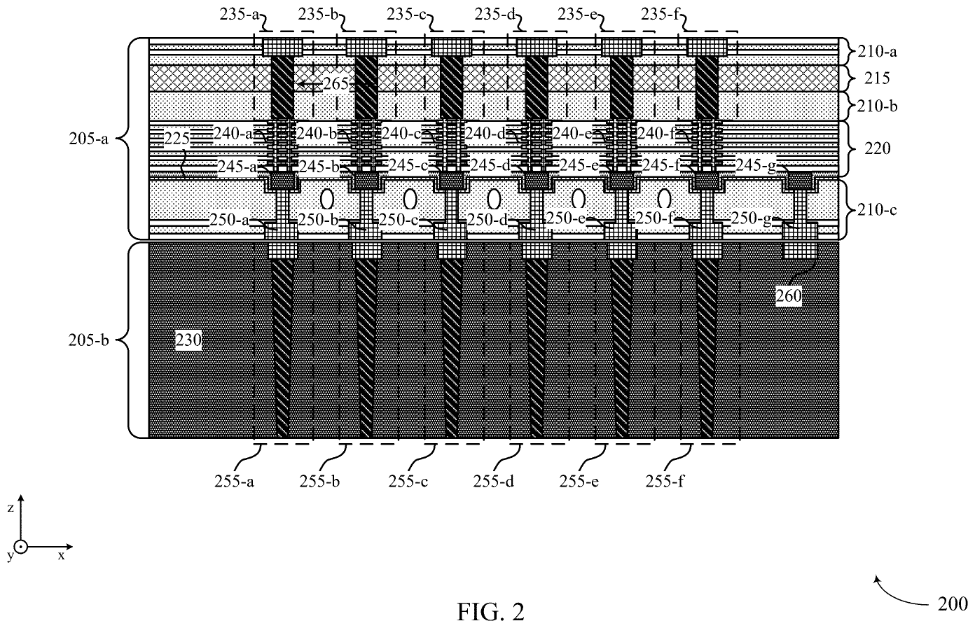

FIG. 2 shows an example of a device 200 that supports reducing resistance in memory devices in accordance with examples as disclosed herein. Aspects of the device 200 may implement, or be implemented by, aspects of the system 100, as described herein with reference to FIG. 1. The device 200 may illustrate a cross section (e.g., x-z cross section) of a stack of dies that include circuitry associated with a PDN, where the PDN may have reduced resistance (e.g., electrical and/or thermal) relative to other PDNs of other devices.

For example, the device 200 may include a die 205-a, which may be an HBM or stacked DRAM die. The die 205-a may include one or more layers that extend a length of the die 205-a in the x-direction. As illustrated, the die 205-a may include an oxide layer 210-a, a silicon layer 215 in contact with the oxide layer 210-a, an oxide layer 210-b in contact with the silicon layer 215, a circuitry layer 220 in contact with the oxide layer 210-b, a copper layer 225 in contact with the circuitry layer 220, and an oxide layer 210-c in contact with the copper layer 225. In some examples, the die 205-a may include one or more airgaps within the oxide layer 210-c, which may facilitate air flow and dissipate heat within the die 205-a.

The die 205-a may include one or more components associated with a PDN of the device 200. For example, the die 205-a may include multiple vias 235 (e.g., TSVs, such as the vias 235-a, 235-b, 235-c, 235-d, 235-e, and 235-f) that are arranged along the die 205-a in the x-direction. Each via 235 may include a copper pad coupled with a tungsten pillar, where each via 235 may extend from an edge of the oxide layer 210-a (e.g., the top of the oxide layer 210-a) through the silicon layer 215 and the oxide layer 210-b and to an edge of the circuitry layer 220 in the z-direction. Additionally, each via 235 may be positioned at a pitch 265 (e.g., 2 micrometers) from one another in the x-direction.

The die 205-a may include BEOL circuitry 240, such as the BEOL circuitry 240-a, 240-b, 240-c, 240-d, 240-e, and 240-f, where the BEOL circuitry 240 may be positioned within a respective portion of the circuitry layer 220. The BEOL circuitry 240 may be composed of a metallic material, such as copper. The die 205-a may also include one or more aluminum pads 245, such as the aluminum pads 245-a, 245-b, 245-c, 245-d, 245-e, and 245-f, and 245-g, where such aluminum pads 245 may be positioned at a boundary (e.g., in the z-direction) between the circuitry layer 220 and the oxide layer 210-c. Each via 235 of the die 205-a may be coupled with a respective aluminum pad 245 via BEOL circuitry 240. For example, the via 235-a may be coupled with the aluminum pad 245-a via the BEOL circuitry 240, while the via 235-f may be coupled with the aluminum pad 245-f via the BEOL circuitry 240-f.

The die 205-a may also include multiple vias 250 (e.g., TOVs), such as the vias 250-a, 250-b, 250-c, 250-d, 250-e, 250-f, and 250-g, where such vias 250 are arranged along the die 205-a in the x-direction. Each of the vias 250 may include (e.g., or be formed of) a metallic material, such as copper. As illustrated, the vias 250 may extend, in the z-direction, from the copper layer 225 through the oxide layer 210-c to an edge of the die 205-a. As illustrated, one or more of the vias 250 may be coupled with respective BEOL circuitry 240 via a respective aluminum pad 245. For example, the via 250-a may be coupled with BEOL circuitry 240-a via the aluminum pad 245-a. The die 205-a may also include the aluminum pad 245-g, which may be coupled with via 250-g, where the aluminum pad 245-g and the via 250-g may be utilized to reduce the resistance (e.g., thermal and/or electrical) of the die 205-a.

The device 200 may also include a die 205-b. For example, the die 205-b may include one or more vias 255 (e.g., TOVs) arranged along the x-direction of the die 205-b, such as the vias 255-a, 255-b, 255-c, 255-d, 255-e, and 255-f. As illustrated, each via 255 may extend, in the z-direction, from a first edge of the die 205-b through an aluminum layer 230 (e.g., data proximity layer) of the die 205-b to a second edge of the die 205-b. Each via 255 may include a copper pad, positioned at the first edge of the die 205-b, coupled with a tungsten pillar that extends through the aluminum layer 230. In some examples, the die 205-b may also include a copper pad 260 at a first side (e.g., right side of the die 205-b in the x-direction) of the die 205-b.

As illustrated, the die 205-a may be bonded with the die 205-b, such that one or more of the vias 250 may be bonded with a respective via 255, while the via 250-g may be bonded with the copper pad 260. For example, the vias 250-a through 250-f may be bonded with a respective via 255, while the via 250-g may be bonded with the copper pad 260. By bonding the die 205-a with the die 205-b, the PDN of the device 200 may be formed. In such examples, the die 205-a and the die 205-b may be bonded according to a hybrid bond. For example, the hybrid bonding may include a fusion bond between the dies 205-a and 205-b and also include a bond between the copper pads of the vias 255 and the copper pads of the vias 250.

The die 205-a and die 205-b may also be bonded according to a face-to-face bonding procedure. For example, the die 205-a may be formed over a first substrate, where the oxide layer 210-a may be in contact with the first substrate. Accordingly, the edge of die 205-a in contact with the first substrate (e.g., the edge that includes the oxide layer 210-a) may be referred to as a back of the die 205-b, while the opposite edge of the die 205-a (e.g., edge that includes the oxide layer 210-c) may be referred to as a face of the die 205-a. Similarly, the die 205-b may be formed over a second substrate, where the edges of the tungsten pillars of the vias 255 may be in contact with the second substrate. Accordingly, the edge of the die 205-b in contact with the second substrate (e.g., the edge that includes the edges of the tungsten pillars) may be referred to as a back of the die 205-b, while the opposite edge of the die 205-b (e.g., the edge that includes the copper pads of the vias 255) may be referred to as the face of the die 205-b. As such, in the face-to-face bonding procedure, the face of the die 205-b (e.g., the edge including the copper pads of the vias 255) may be bonded with the face of the die 205-a (e.g., the edge of the die 205-a including the oxide layer 210-c).

Additionally, in some examples, the die 205-a and the die 205-b may be bonded according to a wafer-to-wafer bonding procedure. In such examples, the die 205-a may be formed on a first wafer that includes multiple dies 205 having a similar, or different, structure to the die 205-a, while the die 205-b may be formed on a second wafer that includes multiple dies 205 having a similar, or different structure to the die 205-b. Accordingly, in the wafer-to-wafer bonding procedure, the first wafer may be bonded with the second wafer, thereby bonding the die 205-a and the die 205-b together.

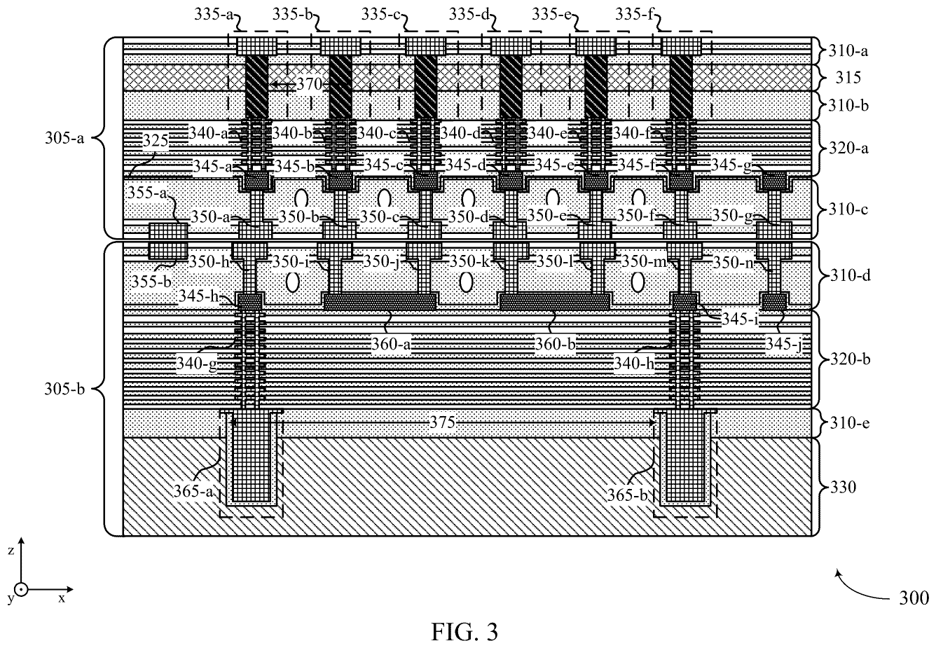

FIG. 3 shows an example of a device 300 that supports reducing resistance in memory devices in accordance with examples as disclosed herein. Aspects of the device 300 may implement, or be implemented by, aspects of the system 100 and the device 200, as described herein with reference to FIGS. 1 and 2. The device 300 may illustrate a cross section of a stack of dies that include circuitry associated with a PDN, where the PDN may have reduced resistance (e.g., electrical and/or thermal) relative to other PDNs of other devices.

For example, the device 300 may include a die 305-a, which may be an example of an HBM or stacked DRAM die or the die 205-a. The die 305-a may include one or more layers of material that extend a length of the die 305-a in the x-direction. As illustrated, the die 305-a may include an oxide layer 310-a, a silicon layer 315 in contact with the oxide layer 310-a, an oxide layer 310-b in contact with the silicon layer 315, a circuitry layer 320-a in contact with the oxide layer 310-b, a copper layer 325 in contact with the circuitry layer 320-a, and an oxide layer 310-c in contact with the copper layer 325. In some examples, the die 305-a may include one or more airgaps within the oxide layer 310-c, which may facilitate air flow and dissipate heat within the die 305-a.

The die 305-a may include one or more components of a PDN of the device 300. For example, the die 305-a may include multiple vias 335, such as the vias 335-a, 335-b, 335-c, 335-d, 335-e, and 335-f, where such vias 335 may be examples of the vias 235 as described herein with reference to FIG. 2. For example, the vias 335 may include a copper pad coupled with a tungsten pillar. As illustrated, the vias 335 may extend, in the z-direction, from an edge of the oxide layer 310-a (e.g., a top of the oxide layer 310-a) through the silicon layer 315 and the oxide layer 310-b to an edge of the circuitry layer 320-a. Additionally, each via 335 may be positioned at a pitch 370 (e.g., 1.25 micro meters) from one another in the x-direction.

The die 305-a may include BEOL circuitry 340, such as the BEOL circuitry 340-a, 340-b, 340-c, 340-d, 340-e, and 340-f, where the BEOL circuitry 340 may be positioned within a respective portion of the circuitry layer 320-a. The BEOL circuitry 340 may be composed of a metallic material, such as copper. The die 305-a may also include one or more aluminum pads 345, such as the aluminum pads 345-a, 345-b, 345-c, 345-d, 345-e, and 345-f, and 345-g, where such aluminum pads 345 may be positioned at a boundary (e.g., in the z-direction) between the circuitry layer 320-a and the oxide layer 310-c. Each via 335 of the die 305-a may be coupled with a respective aluminum pad 345 via BEOL circuitry 340. For example, the via 335-a may be coupled with the aluminum pad 345-a via the BEOL circuitry 340-a, while the via 335-f may be coupled with the aluminum pad 345-f via the BEOL circuitry 340-f.

The die 305-a may also include multiple vias 350, such as the vias 350-a, 350-b, 350-c, 350-d, 350-e, 350-f, and 350-g, where such vias 350 are arranged along the die 305-a in the x-direction. Each of the vias 350 may include (e.g., or be formed of) a metallic material, such as copper. As illustrated, the vias 350 may extend, in the z-direction, from the copper layer 325 through the oxide layer 310-c to an edge of the die 305-a. As illustrated, one or more of the vias 350 may be coupled with respective BEOL circuitry 340 via a respective aluminum pad 345. For example, the via 350-a may be coupled with BEOL circuitry 340-a via the aluminum pad 345-a. The die 305-a may also include the aluminum pad 345-g, which may be coupled with via 350-g. Additionally, the die 305-a may include a copper pad 355-a. In such examples, the aluminum pad 345-g, via 350-g, and copper pad 355-a may be utilized to reduce the resistance (e.g., electrical and/or thermal) of the die 305-a.

The device 300 may also include a die 305-b. The die 305-b may include one or more layers of material that each extend along the die 305-b in the x-direction. For example, the die 305-b may include an oxide layer 310-d, a circuitry layer 320-b in contact with the oxide layer 310-d, an oxide layer 310-e in contact with the circuitry layer 320-b, and a data proximity layer 330 in contact with the oxide layer 310-e. In some examples, the die 305-b may include one or more airgaps within the oxide layer 310-d, which may facilitate air flow and dissipate heat within the die 305-b.

The die 305-b may also include one or more components of the PDN of the device 300. For example, the die 305-b may include one or more vias 350 (e.g., TOVs) arranged along the x-direction of the die 305-b, such as the vias 350-h, 350-i, 350-j, 350-k, 350-m, and 350-n. The vias 350 of the die 305-b may be composed of a metallic material, such as copper. As illustrated, each via 350 may extend, in the z-direction, from a first edge of the die 305-b through the oxide layer 310-d to an edge of the circuitry layer 320-b.

The die 305-b may include one or more aluminum pads 345, such as the aluminum pads 345-h, 345-i, and 345-j. Each aluminum pad 345 may be coupled with a respective via 350 of the die 305-b. For example, the aluminum pad 345-h may be coupled with the via 350-h, the aluminum pad 345-i may be coupled with the via 350-m, and the aluminum pad 345-j may be coupled with the via 350-n. In some examples, one or more vias 350 of the die 305-b may be coupled together via an aluminum line 360. For example, the via 350-i and the via 350-j may be coupled via an aluminum line 360-a, while the via 350-k and the via 350-l may be coupled via the aluminum line 360-b. In some examples, the die 305-b may include one or more copper pads 355, such as the copper pad 355-b positioned within the oxide layer 310-d.

The die 305-b may also include BEOL circuitry 340, such as the BEOL circuitry 340-g and 340-h, which may be positioned in a respective portion of the circuitry layer 320-b. Such BEOL circuitry 340 may be composed of a metallic material, such as copper. In such examples, one or more vias 350 may be coupled with the BEOL circuitry 340 via the aluminum pads 345. For example, the via 350-h may be coupled with the BEOL circuitry 340-g via the aluminum pad 345-h, while the via 350-m may be coupled with the BEOL circuitry 340-h via the aluminum pad 345-i.

In some examples, the die 305-b may include one or more vias 365, such as the via 365-a and the via 365-b. In such examples, the vias 365 may extend, in the z-direction, from an edge of the circuitry layer 320-b through the oxide layer 310-e and into a length (e.g., portion) of the data proximity layer 330. Each via 365 may be composed of a metallic material, such as copper. Additionally, each via 365 may be positioned at a pitch 375 (e.g., 6 to 10 micrometers) from each another in the x-direction.

The vias 365 may be coupled with a respective via 350 via the BEOL circuitry 340 and aluminum pads 345. For example, the via 365-a may be coupled with the via 350-h via the BEOL circuitry 340-g and the aluminum pad 345-h, while the via 365-b may be coupled with the via 350-m via the BEOL circuitry 340-h and the aluminum pad 345-i. As illustrated, the die 305-a may be bonded with the die 305-b, such that a respective via 350 of the die 305-a may be bonded with a respective via 350 of the die 305-b and the copper pad 355-a may be bonded with the copper pad 355-b. By bonding the die 305-a with the die 305-b, the PDN of the device 300 may be formed. In such examples, the die 305-a and the die 305-b may be bonded according to a hybrid bond. For example, the hybrid bonding may include a fusion bond between the dies 305-a and 305-b and also include a bond between the copper pads 355 of the dies 305 and a bond between the copper pads of the vias 350 of the die 305-a and the copper pads of the vias 350 of the die 305-b.

The die 305-a and die 305-b may also be bonded according to a face-to-face bonding procedure. For example, the die 305-a may be formed over a first substrate, where the oxide layer 310-a may be in contact with the first substrate. Accordingly, the edge of die 305-a in contact with the first substrate (e.g., the edge that includes the oxide layer 310-a) may be referred to as a back of the die 305-b, while the opposite edge of the die 305-a (e.g., edge that includes the oxide layer 310-c) may be referred to as a face of the die 305-a. Similarly, the die 305-b may be formed over a second substrate, where the data proximity layer 330 may be in contact with the second substrate. Accordingly, the edge of the die 305-b in contact with the second substrate (e.g., the edge that includes data proximity layer 330) may be referred to as a back of the die 305-b, while the opposite edge of the die 305-b (e.g., the edge that includes the oxide layer 310-d) may be referred to as the face of the die 305-b. As such, in the face-to-face bonding procedure, the face of the die 305-b (e.g., the edge including the oxide layer 310-d) may be bonded with the face of the die 305-a (e.g., the edge of the die 305-a including the oxide layer 310-c).

Additionally, in some examples, the die 305-a and the die 305-b may be bonded according to a wafer-to-wafer bonding procedure. In such examples, the die 305-a may be formed on a first wafer that includes multiple dies 305 having a similar, or different, structure to the die 305-a, while the die 305-b may be formed on a second wafer that includes multiple dies 305 having a similar, or different structure to the die 305-b. Accordingly, in the wafer-to-wafer bonding procedure, the first wafer may be bonded with the second wafer, thereby bonding the die 305-a and the die 305-b together.

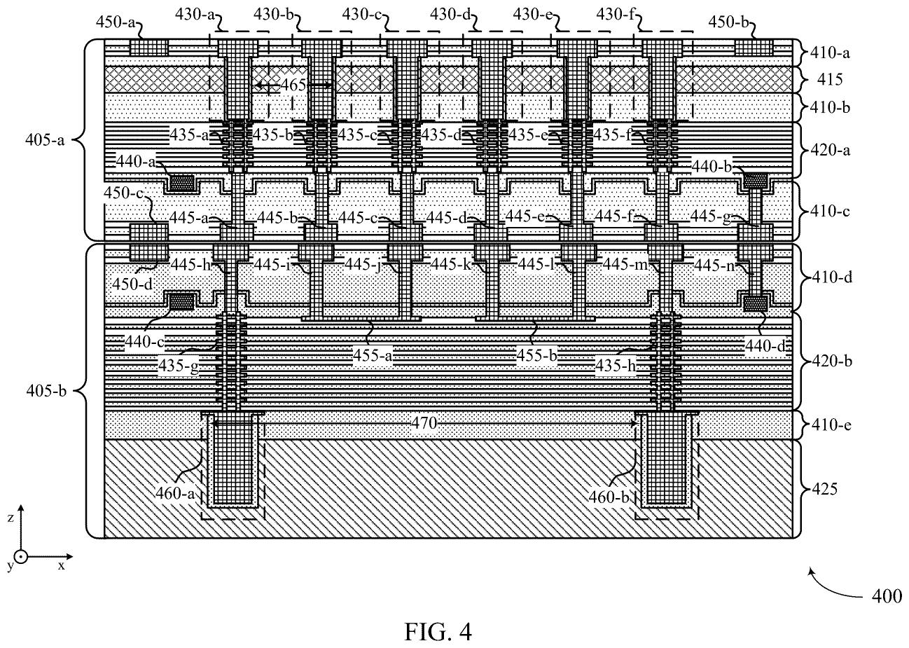

FIG. 4 shows an example of a device 400 that supports reducing resistance in memory devices in accordance with examples as disclosed herein. Aspects of the device 400 may implement, or be implemented by, aspects of the system 100, the device 200, and the device 300, as described herein with reference to FIGS. 1 through 3. The device 400 may illustrate a stack of dies that include circuitry associated with a PDN, where the PDN may have reduced resistance (e.g., electrical and/or thermal) relative to other PDNs of other devices.

For example, the device 400 may include a die 405-a, which may be an example of an HBM or stacked DRAM die, the die 205-a, or the die 305-a. The die 405-a may include one or more layers of material that extend a length of the die 405-a in the x-direction. As illustrated, the die 405-a may include an oxide layer 410-a, a silicon layer 415 in contact with the oxide layer 410-a, an oxide layer 410-b in contact with the silicon layer 415, a circuitry layer 420-a in contact with the oxide layer 410-b, and an oxide layer 410-c in contact with the circuitry layer 420-a. In some examples, the die 405-a may include one or more airgaps within the oxide layer 410-c, which may facilitate air flow and dissipate heat within the die 405-a.

The die 405-a may include one or more components of a PDN of the device 400. For example, the die 405-a may include multiple vias 430, such as the vias 430-a, 430-b, 430-c, 430-d, 430-e, and 430-f. For example, the vias 430 may include a metallic material, such as copper. As illustrated, the vias 430 may extend, in the z-direction, from an edge of the oxide layer 410-a (e.g., a top of the oxide layer 410-a) through the silicon layer 415 and the oxide layer 410-b to an edge of the circuitry layer 420-a. Additionally, each via 430 may be positioned at a pitch 465 (e.g., 2 micrometers) from one another in the x-direction.

The die 405-a may include BEOL circuitry 435, such as the BEOL circuitry 435-a, 435-b, 435-c, 435-d, 435-e, and 435-f, where the BEOL circuitry 435 may be positioned within a respective portion of the circuitry layer 420-a. The BEOL circuitry 435 may be composed of a metallic material, such as copper.

The die 405-a may also include multiple vias 445, such as the vias 445-a, 445-b, 445-c, 445-d, 445-e, 445-f, and 445-g, where such vias 445 are arranged along the die 405-a in the x-direction. Each of the vias 445 may include (e.g., or be formed of) a metallic material, such as copper. As illustrated, the vias 445 may extend, in the z-direction, from an edge of the circuitry layer 420-a through the oxide layer 410-c to an edge of the die 405-a. One or more of the vias 445 may be coupled with respective vias 430 through BEOL circuitry 435. For example, the via 445-a may be coupled with via 430-a via the BEOL circuitry 435-a. The die 405-a may also include one or more aluminum pads 440, such as the aluminum pad 440-a and the aluminum pad 440-b. In such examples, the aluminum pads 440 may be coupled with one or more vias 445. For example, the aluminum pad 440-b may be coupled with the via 445-g.

In some examples, the die 405-a may include one or more copper pads 450, such as a copper pad 450-a and a copper pad 450-b positioned at a respective side, in the x-direction) of the oxide layer 410-a of the die 405-a. Additionally, the die 405-a may include a copper pad 450-c positioned at a first side of the oxide layer 410-c of the die 405-a. Such copper pads 450 may be utilized to bond the die 405-a with other dies 405, reduce resistivity of the die 405-a (e.g., electrical and/or thermal), or both.

The device 400 may also include a die 405-b. The die 405-b may include one or more layers of material that each extend along the die 405-b in the x-direction. For example, the die 405-b may include an oxide layer 410-d, a circuitry layer 420-b in contact with the oxide layer 410-d, an oxide layer 410-e in contact with the circuitry layer 420-b, and a data proximity layer 425 in contact with the oxide layer 410-e. In some examples, the die 405-b may include one or more airgaps within the oxide layer 410-d, which may facilitate air flow and dissipate heat within the die 405-b.

The die 405-b may also include one or more components of the PDN of the device 400. For example, the die 405-b may include one or more vias 445 (e.g., TOVs) arranged along the x-direction of the die 405-b, such as the vias 445-h, 445-i, 445-j, 445-k, 445-m, and 445-n. The vias 445 of the die 405-b may be composed of a metallic material, such as copper. As illustrated, each via 445 may extend, in the z-direction, from a first edge of the die 405-b through the oxide layer 410-d to an edge of the circuitry layer 420-b.

The die 405-b may include one or more aluminum pads 440, such as the aluminum pads 440-c and 440-d. In such examples, one or more of the aluminum pads 440 may be coupled with a respective via 445 of the die 405-b. For example, the aluminum pad 440-d may be coupled with the via 445-n. In some examples, one or more vias 445 of the die 405-b may be coupled together via a copper line 455. For example, the via 445-i and the via 445-j may be coupled via a copper line 455-a, while the via 445-k and the via 445-l may be coupled via the copper line 455-b. In some examples, the die 405-b may include one or more copper pads 450, such as the copper pad 450-d positioned within the oxide layer 410-d.

The die 405-b may also include BEOL circuitry 435, such as the BEOL circuitry 435-g and 435-h, which may be positioned in a respective portion of the circuitry layer 420-b. Such BEOL circuitry 435 may be composed of a metallic material, such as copper. In such examples, one or more vias 445 may be coupled with the BEOL circuitry 435. For example, the via 445-h may be coupled with the BEOL circuitry 435-g, while the via 445-m may be coupled with the BEOL circuitry 435-h.

In some examples, the die 405-b may include one or more vias 460, such as the via 460-a and the via 460-b. In such examples, the vias 460 may extend, in the z-direction, from an edge of the circuitry layer 420-b through the oxide layer 410-e and into a length (e.g., portion) of the data proximity layer 425. Each via 460 may be composed of a metallic material, such as copper. Additionally, each via 460 may be positioned at a pitch 470 (e.g., 6 to 10 micrometers) from each another in the x-direction. The vias 460 may be coupled with a respective via 445 via the BEOL circuitry 435. For example, the via 460-a may be coupled with the via 445-h via the BEOL circuitry 435-g, while the via 460-b may be coupled with the via 445-m via the BEOL circuitry 435-h.

As illustrated, the die 405-a may be bonded with the die 405-b, such that a respective via 445 of the die 405-a may be bonded with a respective via 445 of the die 405-b and the copper pad 450-c may be bonded with the copper pad 450-d. By bonding the die 405-a with the die 405-b, the PDN of the device 400 may be formed. In such examples, the die 405-a and the die 405-b may be bonded according to a hybrid bond. For example, the hybrid bonding may include a fusion bond between the dies 405-a and 405-b and also include a bond between the copper pads 450 of the dies 405 and a bond between the copper pads of the vias 445 of the die 405-a and the copper pads of the vias 445 of the die 405-b.

The die 405-a and die 405-b may also be bonded according to a face-to-face bonding procedure. For example, the die 405-a may be formed over a first substrate, where the oxide layer 410-a may be in contact with the first substrate. Accordingly, the edge of die 405-a in contact with the first substrate (e.g., the edge that includes the oxide layer 410-a) may be referred to as a back of the die 405-b, while the opposite edge of the die 405-a (e.g., edge that includes the oxide layer 410-c) may be referred to as a face of the die 405-a. Similarly, the die 405-b may be formed over a second substrate, where the data proximity layer 425 may be in contact with the second substrate. Accordingly, the edge of the die 405-b in contact with the second substrate (e.g., the edge that includes data proximity layer 425) may be referred to as a back of the die 405-b, while the opposite edge of the die 405-b (e.g., the edge that includes the oxide layer 410-d) may be referred to as the face of the die 405-b. As such, in the face-to-face bonding procedure, the face of the die 405-b (e.g., the edge of the die 405-b including the oxide layer 410-d) may be bonded with the face of the die 405-a (e.g., the edge of the die 405-a including the oxide layer 410-c).

Additionally, in some examples, the die 405-a and the die 405-b may be bonded according to a wafer-to-wafer bonding procedure. In such examples, the die 405-a may be formed on a first wafer that includes multiple dies 405 having a similar, or different, structure to the die 405-a, while the die 405-b may be formed on a second wafer that includes multiple dies 405 having a similar, or different structure to the die 405-b. Accordingly, in the wafer-to-wafer bonding procedure, the first wafer may be bonded with the second wafer, thereby bonding the die 405-a and the die 405-b together.

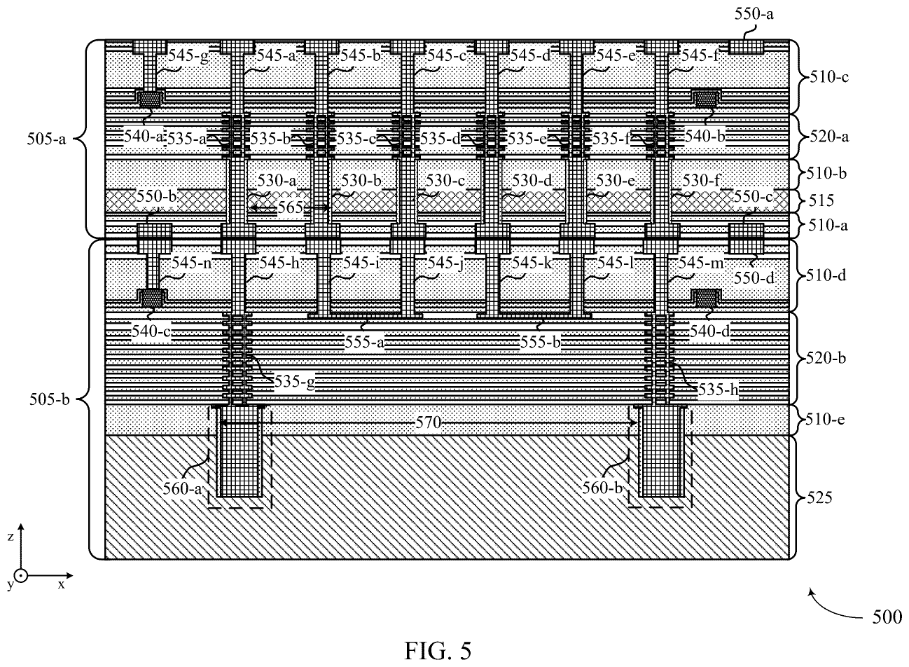

FIG. 5 shows an example of a device 500 that supports reducing resistance in memory devices in accordance with examples as disclosed herein. Aspects of the device 500 may implement, or be implemented by, aspects of the system 100, the device 200, the device 300, and the device 400, as described herein with reference to FIGS. 1 through 4. The device 500 may illustrate a stack of dies that include circuitry associated with a PDN, where the PDN may have reduced resistance (e.g., electrical and/or thermal) relative to other PDNs of other devices.

For example, the device 500 may include a die 505-a, which may be an example of an HBM or stacked DRAM die, the die 205-a, the die 305-a, or the die 405-a. The die 505-a may include one or more layers of material that extend a length of the die 505-a in the x-direction. As illustrated, the die 505-a may include an oxide layer 510-a, a silicon layer 515 in contact with the oxide layer 510-a, an oxide layer 510-b in contact with the silicon layer 515, a circuitry layer 520-a in contact with the oxide layer 510-b, and an oxide layer 510-c in contact with the circuitry layer 520-a. In some examples, the die 505-a may include one or more airgaps within the oxide layer 510-a, which may facilitate air flow and dissipate heat within the die 505-a.

The die 505-a may include one or more components of a PDN of the device 500. For example, the die 505-a may include multiple vias 530, such as the vias 530-a, 530-b, 530-c, 530-d, 530-e, and 530-f. For example, the vias 530 may include a metallic material, such as copper. As illustrated, the vias 530 may extend, in the z-direction, from an edge of the oxide layer 510-a (e.g., a bottom of the oxide layer 510-a) through the silicon layer 515 and the oxide layer 510-b to an edge of the circuitry layer 520-a. Additionally, each via 530 may be positioned at a pitch 565 (e.g., 2 micrometers) from one another in the x-direction.

The die 505-a may include BEOL circuitry 535, such as the BEOL circuitry 535-a, 535-b, 535-c, 535-d, 535-e, and 535-f, where the BEOL circuitry 535 may be positioned within a respective portion of the circuitry layer 520-a. The BEOL circuitry 535 may be composed of a metallic material, such as copper. The die 505-a may also include multiple vias 545, such as the vias 545-a, 545-b, 545-c, 545-d, 545-e, 545-f, and 545-g, where such vias 545 are arranged along the die 505-a in the x-direction. Each of the vias 545 may include (e.g., or be formed of) a metallic material, such as copper. As illustrated, the vias 545 may extend, in the z-direction, from an edge of the circuitry layer 520-a through the oxide layer 510-c to an edge of the die 505-a.

Each via 530 of the die 505-a may be coupled with a respective via 545 via BEOL circuitry 535. For example, the via 545-a may be coupled with the via 530-a via the BEOL circuitry 535-a, while the via 545-f may be coupled with the via 530-f via the BEOL circuitry 535-f. The die 505-a may also include an aluminum pad 540-a, which may be coupled with via 545-g, and also include an aluminum pad 540-b, where such aluminum pads 540 may be positioned at a boundary (e.g., in the z-direction) between the circuitry layer 520-a and the oxide layer 510-c.

In some examples, the die 505-a may include one or more copper pads 550, such as a copper pad 550-b and a copper pad 550-c positioned at a respective side, in the x-direction) of the oxide layer 510-a of the die 505-a. Additionally, the die 505-a may include a copper pad 550-a positioned at a first side of the oxide layer 510-c of the die 505-a. Such copper pads 550 may be utilized to bond the die 505-a with other dies 505, reduce resistivity of the die 505-a (e.g., electrical and/or thermal), or both.

The device 500 may also include a die 505-b. The die 505-b may include one or more layers of material that each extend along the die 505-b in the x-direction. For example, the die 505-b may include an oxide layer 510-d, a circuitry layer 520-b in contact with the oxide layer 510-d, an oxide layer 510-e in contact with the circuitry layer 520-b, and a data proximity layer 525 in contact with the oxide layer 510-e. In some examples, the die 505-b may include one or more airgaps within the oxide layer 510-d, which may facilitate air flow and dissipate heat within the die 505-b.

The die 505-b may also include one or more components of the PDN of the device 500. For example, the die 505-b may include one or more vias 545 (e.g., TOVs) arranged along the x-direction of the die 505-b, such as the vias 545-h, 545-i, 545-j, 545-k, 545-m, and 545-n. The vias 545 of the die 505-b may be composed of a metallic material, such as copper. As illustrated, each via 545 may extend, in the z-direction, from a first edge of the die 505-b through the oxide layer 510-d to an edge of the circuitry layer 520-b.

In some examples, one or more vias 545 of the die 505-b may be coupled together via a copper line 555. For example, the via 545-i and the via 545-j may be coupled via a copper line 555-a, while the via 545-k and the via 545-l may be coupled via the copper line 555-b. The die 505-b may also include one or more aluminum pads 540, such as the aluminum pads 540-c and 540-d, where one or more vias 545 of the die 505-b may be coupled with an aluminum pad 540. For example, the via 545-n may be coupled with the aluminum pad 540-c. In some examples, the die 505-b may include one or more copper pads 550, such as the copper pad 550-d positioned within the oxide layer 510-d.

The die 505-b may also include BEOL circuitry 535, such as the BEOL circuitry 535-g and 535-h, which may be positioned in a respective portion of the circuitry layer 520-b. Such BEOL circuitry 535 may be composed of a metallic material, such as copper. In some examples, the die 505-b may include one or more vias 560, such as the via 560-a and the via 560-b. In such examples, the vias 560 may extend, in the z-direction, from an edge of the circuitry layer 520-b through the oxide layer 510-e and into a length (e.g., portion) of the data proximity layer 525. Each via 560 may be composed of a metallic material, such as copper. Additionally, each via 560 may be positioned at a pitch 570 (e.g., 6 to 10 micrometers) from each another in the x-direction. The vias 560 may be coupled with a respective via 545 via the BEOL circuitry 535. For example, the via 560-a may be coupled with the via 545-h via the BEOL circuitry 535-g, while the via 560-b may be coupled with the via 545-m via the BEOL circuitry 535-h.

As illustrated, the die 505-a may be bonded with the die 505-b, such that a respective via 530 of the die 505-a may be bonded with a respective via 545 of the die 505-b, such that the copper pad 550-b may be coupled with the via 545-n, and the copper pad 550-c may be bonded with the copper pad 550-d. By bonding the die 505-a with the die 505-b, the PDN of the device 500 may be formed. In such examples, the die 505-a and the die 505-b may be bonded according to a hybrid bond. For example, the hybrid bonding may include a fusion bond between the dies 505-a and 505-b and also include a bond between the copper pads 550 of the dies 505 and a bond between the copper pads of the vias 530 of the die 505-a and the copper pads of the vias 545 of the die 505-b.

The die 505-a and die 505-b may also be bonded according to a face-to-back bonding procedure. For example, the die 505-a may be formed over a first substrate, where the oxide layer 510-a may be in contact with the first substrate. Accordingly, the edge of die 505-a in contact with the first substrate (e.g., the edge that includes the oxide layer 510-a) may be referred to as a back of the die 505-b, while the opposite edge of the die 505-a (e.g., edge that includes the oxide layer 510-c) may be referred to as a face of the die 505-a. Similarly, the die 505-b may be formed over a second substrate, where the data proximity layer 525 may be in contact with the second substrate. Accordingly, the edge of the die 505-b in contact with the second substrate (e.g., the edge that includes data proximity layer 525) may be referred to as a back of the die 505-b, while the opposite edge of the die 505-b (e.g., the edge that includes the oxide layer 510-d) may be referred to as the face of the die 505-b. As such, in the face-to-back bonding procedure, in response to forming the die 505-a, the oxide layer 510-c may be coupled with a sacrificial substrate (or other material), while the first substrate may be removed from the oxide layer 510-a, thereby freeing the back of the die 505-a. As such, the face of the die 505-b (e.g., the edge of the die 505-b including the oxide layer 510-d) may be bonded with the back of the die 505-a (e.g., the edge of the die 505-a including the oxide layer 510-a).

Additionally, in some examples, the die 505-a and the die 505-b may be bonded according to a wafer-to-wafer bonding procedure. In such examples, the die 505-a may be formed on a first wafer that includes multiple dies 505 having a similar, or different, structure to the die 505-a, while the die 505-b may be formed on a second wafer that includes multiple dies 505 having a similar, or different structure to the die 505-b. Accordingly, in the wafer-to-wafer bonding procedure, the first wafer may be bonded with the second wafer, thereby bonding the die 505-a and the die 505-b together.

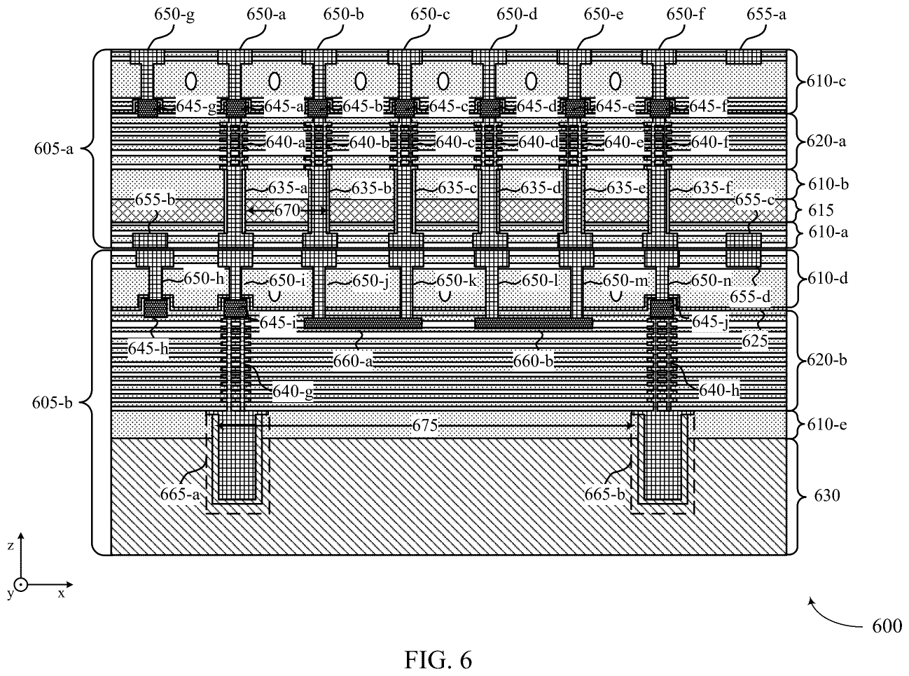

FIG. 6 shows an example of a device 600 that supports reducing resistance in memory devices in accordance with examples as disclosed herein. Aspects of the device 600 may implement, or be implemented by, aspects of the system 100, the device 200, the device 300, the device 400, and the device 500, as described herein with reference to FIGS. 1 through 5. The device 600 may illustrate a stack of dies that include circuitry associated with a PDN, where the PDN may have reduced resistance (e.g., electrical and/or thermal) relative to other PDNs of other devices.

For example, the device 600 may include a die 605-a, which may be an example of an HBM or stacked DRAM die, the die 205-a, the die 305-a, or the die 405-a. The die 605-a may include one or more layers of material that extend a length of the die 605-a in the x-direction. As illustrated, the die 605-a may include an oxide layer 610-a, a silicon layer 615 in contact with the oxide layer 610-a, an oxide layer 610-b in contact with the silicon layer 615, a circuitry layer 620-a in contact with the oxide layer 610-b, and an oxide layer 610-c in contact with the circuitry layer 620-a. In some examples, the die 605-a may include one or more airgaps within the oxide layer 610-c, which may facilitate air flow and dissipate heat within the die 605-a.

The die 605-a may include one or more components of a PDN of the device 600. For example, the die 605-a may include multiple vias 635, such as the vias 635-a, 635-b, 635-c, 635-d, 635-e, and 635-f. For example, the vias 635 may include a metallic material, such as copper. As illustrated, the vias 635 may extend, in the z-direction, from an edge of the oxide layer 610-a (e.g., a bottom of the oxide layer 610-a) through the silicon layer 615 and the oxide layer 610-b to an edge of the circuitry layer 620-a. Additionally, each via 635 may be positioned at a pitch 670 (e.g., 2 micrometers) from one another in the x-direction.

The die 605-a may include BEOL circuitry 640, such as the BEOL circuitry 640-a, 640-b, 640-c, 640-d, 640-e, and 640-f, where the BEOL circuitry 640 may be positioned within a respective portion of the circuitry layer 620-a. The BEOL circuitry 640 may be composed of a metallic material, such as copper. The die 605-a may include one or more aluminum pads 645, such as the aluminum pads 645-a, 645-b, 645-c, 645-d, 645-e, 645-f, and 645-g.

The die 605-a may also include multiple vias 650, such as the vias 650-a, 650-b, 650-c, 650-d, 650-e, 650-f, and 650-g, where such vias 650 are arranged along the die 605-a in the x-direction. Each of the vias 650 may include (e.g., or be formed of) a metallic material, such as copper. As illustrated, the vias 650 may extend, in the z-direction, from an edge of the circuitry layer 620-a through the oxide layer 610-c to an edge of the die 605-a.

Each via 635 of the die 605-a may be coupled with a respective via 650 via BEOL circuitry 640 and aluminum pad 645. For example, the via 650-a may be coupled with the via 635-a via the BEOL circuitry 640-a and the aluminum pad 645-a, while the via 650-f may be coupled with the via 635-f via the BEOL circuitry 640-f and the aluminum pad 645-f. The die 605-a may also include the aluminum pad 645-g, which may be coupled with via 650-g.

In some examples, the die 605-a may include one or more copper pads 655, such as a copper pad 655-b and a copper pad 655-c positioned at a respective side, in the x-direction) of the oxide layer 610-a of the die 605-a. Additionally, the die 605-a may include a copper pad 655-a positioned at a first side of the oxide layer 610-c of the die 605-a. Such copper pads 655 may be utilized to bond the die 605-a with other dies 605, reduce resistivity of the die 605-a (e.g., electrical and/or thermal), or both.

The device 600 may also include a die 605-b. The die 605-b may include one or more layers of material that each extend along the die 605-b in the x-direction. For example, the die 605-b may include an oxide layer 610-d, a copper layer 625 in contact with the oxide layer 610-d, a circuitry layer 620-b in contact with the copper layer 625, an oxide layer 610-e in contact with the circuitry layer 620-b, and a data proximity layer 630 in contact with the oxide layer 610-e. In some examples, the die 605-b may include one or more airgaps within the oxide layer 610-d, which may facilitate air flow and dissipate heat within the die 605-b.

The die 605-b may also include one or more components of the PDN of the device 600. For example, the die 605-b may include one or more vias 650 (e.g., TOVs) arranged along the x-direction of the die 605-b, such as the vias 650-h, 650-i, 650-j, 650-k, 650-m, and 650-n. The vias 650 of the die 605-b may be composed of a metallic material, such as copper. As illustrated, each via 650 may extend, in the z-direction, from a first edge of the die 605-b through the oxide layer 610-d to an edge of the circuitry layer 620-b.

In some examples, one or more vias 650 of the die 605-b may be coupled together via an aluminum line 660. For example, the via 650-i and the via 650-j may be coupled via an aluminum line 660-a, while the via 650-k and the via 650-l may be coupled via the aluminum line 660-b. The die 605-b may also include one or more aluminum pads 645, such as the aluminum pads 645-h, 645-i, and 645-j, where one or more vias 650 of the die 605-b may be coupled with an aluminum pad 645. For example, the via 650-h may be coupled with the aluminum pad 645-h, the via 650-i may be coupled with the aluminum pad 645-i, and the via 650-n may be coupled with the aluminum pad 645-j. In some examples, the die 605-b may include one or more copper pads 655, such as the copper pad 655-d positioned within the oxide layer 610-d.

The die 605-b may also include BEOL circuitry 640, such as the BEOL circuitry 640-g and 640-h, which may be positioned in a respective portion of the circuitry layer 620-b. Such BEOL circuitry 640 may be composed of a metallic material, such as copper. In some examples, the die 605-b may include one or more vias 665 (e.g., TSVs), such as the via 665-a and the via 665-b. In such examples, the vias 665 may extend, in the z-direction, from an edge of the circuitry layer 620-b through the oxide layer 610-e and into a length (e.g., portion) of the data proximity layer 630. Each via 665 may be composed of a metallic material, such as copper. Additionally, each via 665 may be positioned at a pitch 675 (e.g., 6 to 10 micrometers) from each another in the x-direction. The vias 665 may be coupled with a respective via 650 via the BEOL circuitry 640 and aluminum pads 645. For example, the via 665-a may be coupled with the via 650-h via the BEOL circuitry 640-g and the aluminum pad 645-i, while the via 665-b may be coupled with the via 650-n via the BEOL circuitry 640-h and the aluminum pad 645-j.

As illustrated, the die 605-a may be bonded with the die 605-b, such that a respective via 635 of the die 605-a may be bonded with a respective via 650 of the die 605-b, such that the copper pad 655-b may be coupled with the via 650-h, and the copper pad 655-c may be bonded with the copper pad 655-d. By bonding the die 605-a with the die 605-b, the PDN of the device 600 may be formed. In such examples, the die 605-a and the die 605-b may be bonded according to a hybrid bond. For example, the hybrid bonding may include a fusion bond between the dies 605-a and 605-b and also include a bond between the copper pads 655 of the dies 605 and a bond between the copper pads of the vias 635 of the die 605-a and the copper pads of the vias 650 of the die 605-b.

The die 605-a and die 605-b may also be bonded according to a face-to-back bonding procedure. For example, the die 605-a may be formed over a first substrate, where the oxide layer 610-a may be in contact with the first substrate. Accordingly, the edge of die 605-a in contact with the first substrate (e.g., the edge that includes the oxide layer 610-a) may be referred to as a back of the die 605-b, while the opposite edge of the die 605-a (e.g., edge that includes the oxide layer 610-c) may be referred to as a face of the die 605-a. Similarly, the die 605-b may be formed over a second substrate, where the data proximity layer 630 may be in contact with the second substrate. Accordingly, the edge of the die 605-b in contact with the second substrate (e.g., the edge that includes data proximity layer 630) may be referred to as a back of the die 605-b, while the opposite edge of the die 605-b (e.g., the edge that includes the oxide layer 610-d) may be referred to as the face of the die 605-b. As such, in the face-to-back bonding procedure, in response to forming the die 605-a, the oxide layer 610-c may be coupled with a sacrificial substrate (or other material), while the first substrate may be removed from the oxide layer 610-a, thereby freeing the back of the die 605-a. As such, the face of the die 605-b (e.g., the edge of the die 605-b including the oxide layer 610-d) may be bonded with the back of the die 605-a (e.g., the edge of the die 605-a including the oxide layer 610-a).

Additionally, in some examples, the die 605-a and the die 605-b may be bonded according to a wafer-to-wafer bonding procedure. In such examples, the die 605-a may be formed on a first wafer that includes multiple dies 605 having a similar, or different, structure to the die 605-a, while the die 605-b may be formed on a second wafer that includes multiple dies 605 having a similar, or different structure to the die 605-b. Accordingly, in the wafer-to-wafer bonding procedure, the first wafer may be bonded with the second wafer, thereby bonding the die 605-a and the die 605-b together.

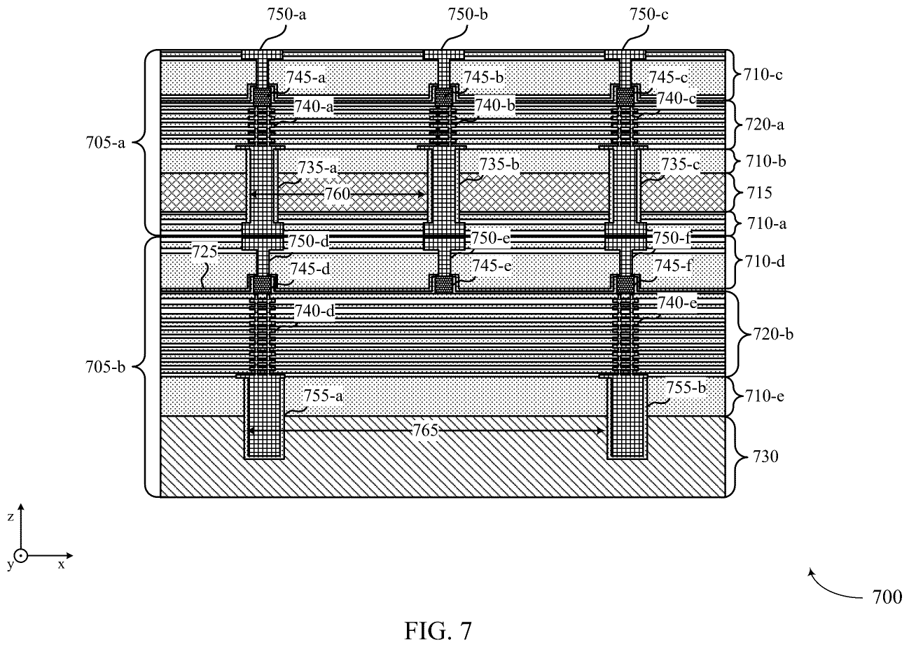

FIG. 7 shows an example of a device 700 that supports reducing resistance in memory devices in accordance with examples as disclosed herein. Aspects of the device 700 may implement, or be implemented by, aspects of the system 100, the device 200, the device 300, the device 400, the device 500, and the device 600, as described herein with reference to FIGS. 1 through 6. The device 700 may illustrate a stack of dies that include circuitry associated with a PDN, where the PDN may have reduced resistance (e.g., electrical and/or thermal) relative to other PDNs of other devices.

For example, the device 700 may include a die 705-a, which may be an example of an HBM or stacked DRAM die, the die 205-a, the die 305-a, the die 405-a, the die 505-a, or the die 605-a. The die 705-a may include one or more layers of material that extend a length of the die 705-a in the x-direction. As illustrated, the die 705-a may include an oxide layer 710-a, a silicon layer 715 in contact with the oxide layer 710-a, an oxide layer 710-b in contact with the silicon layer 715, a circuitry layer 720-a in contact with the oxide layer 710-b, and an oxide layer 710-c in contact with the circuitry layer 720-a. In some examples, the die 705-a may include one or more airgaps within the oxide layer 710-c, which may facilitate air flow and dissipate heat within the die 705-a.

The die 705-a may include one or more components of a PDN of the device 700. For example, the die 705-a may include multiple vias 735, such as the vias 735-a, 735-b, and 735-c. For example, the vias 735 may include a metallic material, such as copper. As illustrated, the vias 735 may extend, in the z-direction, from an edge of the oxide layer 710-a (e.g., a bottom of the oxide layer 710-a) through the silicon layer 715 and the oxide layer 710-b to an edge of the circuitry layer 720-a. Additionally, each via 735 may be positioned at a pitch 760 (e.g., 3 micrometers) from one another in the x-direction.

The die 705-a may include BEOL circuitry 740, such as the BEOL circuitry 740-a, 740-b, and 740-c, where the BEOL circuitry 740 may be positioned within a respective portion of the circuitry layer 720-a. The BEOL circuitry 740 may be composed of a metallic material, such as copper. The die 705-a may include one or more aluminum pads 745, such as the aluminum pads 745-a, 745-b, and 745-c. The die 705-a may also include multiple vias 750, such as the vias 750-a, 750-b, and 750-c, where such vias 750 are arranged along the die 705-a in the x-direction. Each of the vias 750 may include (e.g., or be formed of) a metallic material, such as copper. As illustrated, the vias 750 may extend, in the z-direction, from an edge of the circuitry layer 720-a through the oxide layer 710-c to an edge of the die 705-a. Each via 735 of the die 705-a may be coupled with a respective via 750 via BEOL circuitry 740 and aluminum pad 745. For example, the via 750-a may be coupled with the via 735-a via the BEOL circuitry 740-a and the aluminum pad 745-a, while the via 750-c may be coupled with the via 735-c via the BEOL circuitry 740-c and the aluminum pad 745-c.

The device 700 may also include a die 705-b. The die 705-b may include one or more layers of material that each extend along the die 705-b in the x-direction. For example, the die 705-b may include an oxide layer 710-d, a copper layer 725 in contact with the oxide layer 710-d, a circuitry layer 720-b in contact with the copper layer 725, an oxide layer 710-e in contact with the circuitry layer 720-b, and a data proximity layer 730 in contact with the oxide layer 710-e. In some examples, the die 705-b may include one or more airgaps within the oxide layer 710-d, which may facilitate air flow and dissipate heat within the die 705-b.

The die 705-b may also include one or more components of the PDN of the device 700. For example, the die 705-b may include one or more vias 750 (e.g., TOVs) arranged along the x-direction of the die 705-b, such as the vias 750-d, 750-e, and 750-f. The vias 750 of the die 705-b may be composed of a metallic material, such as copper. As illustrated, each via 750 may extend, in the z-direction, from a first edge of the die 705-b through the oxide layer 710-d to an edge of the circuitry layer 720-b.

The die 705-b may also include one or more aluminum pads 745, such as the aluminum pads 745-d, 745-e, and 745-f, where one or more vias 750 of the die 705-b may be coupled with an aluminum pad 745. For example, the via 750-d may be coupled with the aluminum pad 745-d, the via 750-e may be coupled with the aluminum pad 745-e, and the via 750-f may be coupled with the aluminum pad 745-f.

The die 705-b may also include BEOL circuitry 740, such as the BEOL circuitry 740-d and 740-e, which may be positioned in a respective portion of the circuitry layer 720-b. Such BEOL circuitry 740 may be composed of a metallic material, such as copper. In some examples, the die 705-b may include one or more vias 755 (e.g., TSVs), such as the via 755-a and the via 755-b. In such examples, the vias 755 may extend, in the z-direction, from an edge of the circuitry layer 720-b through the oxide layer 710-e and into a length (e.g., portion) of the data proximity layer 730. Each via 755 may be composed of a metallic material, such as copper. Additionally, each via 755 may be positioned at a pitch 765 (e.g., 6 to 10 micrometers) from each another in the x-direction. The vias 755 may be coupled with a respective via 750 via the BEOL circuitry 740 and aluminum pads 745. For example, the via 755-a may be coupled with the via 750-d via the BEOL circuitry 740-d and the aluminum pad 745-d, while the via 755-b may be coupled with the via 750-f via the BEOL circuitry 740-e and the aluminum pad 745-f.

As illustrated, the die 705-a may be bonded with the die 705-b, such that a respective via 735 of the die 705-a may be bonded with a respective via 750 of the die 705-b. By bonding the die 705-a with the die 705-b, the PDN of the device 700 may be formed. In such examples, the die 705-a and the die 705-b may be bonded according to a hybrid bond. For example, the hybrid bonding may include a fusion bond between the dies 705-a and 705-b and also include a bond between the copper pads of the vias 735 of the die 705-a and the copper pads of the vias 750 of the die 705-b.

The die 705-a and the die 705-b may also be bonded according to a face-to-back bonding procedure. For example, the die 705-a may be formed over a first substrate, where the oxide layer 710-a may be in contact with the first substrate. Accordingly, the edge of die 705-a in contact with the first substrate (e.g., the edge that includes the oxide layer 710-a) may be referred to as a back of the die 705-b, while the opposite edge of the die 705-a (e.g., edge that includes the oxide layer 710-c) may be referred to as a face of the die 705-a. Similarly, the die 705-b may be formed over a second substrate, where the data proximity layer 730 may be in contact with the second substrate. Accordingly, the edge of the die 705-b in contact with the second substrate (e.g., the edge that includes data proximity layer 730) may be referred to as a back of the die 705-b, while the opposite edge of the die 705-b (e.g., the edge that includes the oxide layer 710-d) may be referred to as the face of the die 705-b. As such, in the face-to-back bonding procedure, in response to forming the die 705-a, the oxide layer 710-c may be coupled with a sacrificial substrate (or other material), while the first substrate may be removed from the oxide layer 710-a, thereby freeing the back of the die 705-a. As such, the face of the die 705-b (e.g., the edge of the die 705-b including the oxide layer 710-d) may be bonded with the back of the die 705-a (e.g., the edge of the die 705-a including the oxide layer 710-a).

Additionally, in some examples, the die 705-a and the die 705-b may be bonded according to a wafer-to-wafer bonding procedure. In such examples, the die 705-a may be formed on a first wafer that includes multiple dies 705 having a similar, or different, structure to the die 705-a, while the die 705-b may be formed on a second wafer that includes multiple dies 705 having a similar, or different structure to the die 705-b. Accordingly, in the wafer-to-wafer bonding procedure, the first wafer may be bonded with the second wafer, thereby bonding the die 705-a and the die 705-b together.

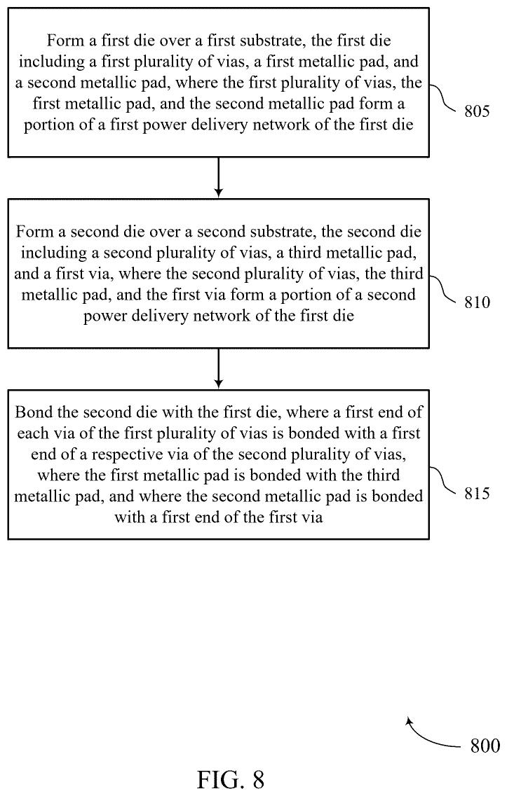

FIG. 8 shows a flowchart illustrating a method 800 that supports reducing resistance in memory systems in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method 800 may include forming a first die over a first substrate, the first die including a first plurality of vias, a first metallic pad, and a second metallic pad, where the first plurality of vias, the first metallic pad, and the second metallic pad form a portion of a first power delivery network of the first die.

At 810, the method 800 may include forming a second die over a second substrate, the second die including a second plurality of vias, a third metallic pad, and a first via, where the second plurality of vias, the third metallic pad, and the first via form a portion of a second power delivery network of the first die.

At 815, the method 800 may include bonding the second die with the first die, where a first end of each via of the first plurality of vias is bonded with a first end of a respective via of the second plurality of vias, where the first metallic pad is bonded with the third metallic pad, and where the second metallic pad is bonded with a first end of the first via.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a first die over a first substrate, the first die including a first plurality of vias, a first metallic pad, and a second metallic pad, where the first plurality of vias, the first metallic pad, and the second metallic pad form a portion of a first power delivery network of the first die; forming a second die over a second substrate, the second die including a second plurality of vias, a third metallic pad, and a first via, where the second plurality of vias, the third metallic pad, and the first via form a portion of a second power delivery network of the first die; and bonding the second die with the first die, where a first end of each via of the first plurality of vias is bonded with a first end of a respective via of the second plurality of vias, where the first metallic pad is bonded with the third metallic pad, and where the second metallic pad is bonded with a first end of the first via.
Aspect 2: The method or apparatus of aspect 1, further including operations, features, circuitry, logic, means, or instructions, or any combination thereof for forming a plurality of first dies including the first die on a first wafer; forming a plurality of second dies including the second die on a second wafer; and bonding the first wafer with the second wafer, where bonding the second die with the first die is based at least in part on bonding the first wafer with the second wafer.
Aspect 3: The method or apparatus of any of aspects 1 through 2, where the second die and the first die are bonded via a hybrid bond.
Aspect 4: The method or apparatus of any of aspects 1 through 3, where a face of the second die is bonded with a back of the first die.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 5: A memory device, including: a first die including a first plurality of vias, a first metallic pad, and a second metallic pad, where the first plurality of vias, the first metallic pad, and the second metallic pad are associated with a first power delivery network of the first die; and a second die including a second plurality of vias, a third metallic pad, and a first via, where the second plurality of vias, the third metallic pad, and the first via are associated with a second power delivery network of the second die, and where a first end of each via of the first plurality of vias is coupled with a first end of a respective via of the second plurality of vias, where the first metallic pad is coupled with the third metallic pad, and where the second metallic pad is coupled with a first end of the first via.
Aspect 6: The memory device of aspect 5, where a second end of a first via of the second plurality of vias is coupled with a second end of a second via of the second plurality of vias by a first metallic line, and a second end of a third via of the second plurality of vias is coupled with a second end of a fourth via of the second plurality of vias via a second metallic line.
Aspect 7: The memory device of aspect 6, where the first metallic line and the second metallic line include copper or aluminum.
Aspect 8: The memory device of any of aspects 6 through 7, where the second die further includes: a third plurality of vias, where a second end of a fifth via of the second plurality of vias is coupled with a first end of a first via of the third plurality of vias via a first portion of circuitry, and where a second end of a sixth via of the second plurality of vias is coupled with a first end of a second via of the third plurality of vias via a second portion of the circuitry.
Aspect 9: The memory device of aspect 8, where the second end of the fifth via is coupled with a fourth metallic pad and the fourth metallic pad is coupled with the first portion of the circuitry, and the second end of the sixth via is coupled with a sixth metallic pad and the sixth metallic pad is coupled with the second portion of the circuitry.
Aspect 10: The memory device of any of aspects 5 through 9, where a second end of the first via is coupled with a fourth metallic pad.
Aspect 11: The memory device of any of aspects 5 through 10, where the first die further includes: a third plurality of vias, where a second end of each via of the first plurality of vias is coupled with a first end of each via of the third plurality of vias via a respective portion of circuitry.
Aspect 12: The memory device of aspect 11, where the first end of each via of the third plurality of vias is coupled with a respective fourth metallic pad, and each respective fourth metallic pad is coupled with the respective portion of the circuitry.
Aspect 13: The memory device of any of aspects 5 through 12, where: the first die further includes a first oxide layer, a silicon layer over the first oxide layer, a second oxide layer over the first oxide layer, a circuitry layer over the first oxide layer, and a third oxide layer over the circuitry layer, and the second die further includes a data proximity layer, a fourth oxide layer over the data proximity layer, a second circuitry layer over the fourth oxide layer, and fifth oxide layer over the second circuitry layer.
Aspect 14: The memory device of aspect 13, where the second die further includes a metallic layer between the circuitry layer and the fourth oxide layer.
Aspect 15: The memory device of any of aspects 13 through 14, where: the first plurality of vias extend through the first oxide layer, the silicon layer, and the second oxide layer of the first die in a first direction, and the first metallic pad and the second metallic pad extend through a portion of the first oxide layer in the first direction.

Aspect 16: The memory device of any of aspects 13 through 15, where: the second plurality of vias and the first via extend through the fifth oxide layer and into a portion of the second circuitry layer in a first direction, and the third metallic pad extends through a portion of the fifth oxide layer in the first direction.

Aspect 17: The memory device of any of aspects 5 through 16, where the first power delivery network and the second power delivery network form a third power delivery network for the memory device in accordance with the first end of each via of the first plurality of vias being coupled with the first end of the respective via of the second plurality of vias, with the first metallic pad being coupled with the third metallic pad, and with the second metallic pad being coupled with the first end of the first via.

Aspect 18: The memory device of any of aspects 5 through 17, where the second die and the first die are coupled together via a hybrid bond.

An apparatus is described. The following provides an overview of aspects of the apparatus as described herein:
Aspect 19: A memory device, including: a first die including a first plurality of vias and a second plurality of vias, where a first end of each via of the second plurality of vias is coupled with a first end of a respective via of the first plurality of vias, and where the first plurality of vias and the second plurality of vias are associated with a first power delivery network of the first die; and a second die including a third plurality of vias and a fourth plurality of vias, where a first end of each via of the fourth plurality of vias is coupled with a first end of a respective via of the fourth plurality of vias, where the third plurality of vias and the fourth plurality of vias are associated with a second power delivery network of the second die, and where a second end of each via of the first plurality of vias is coupled with a second end of a respective via of the third plurality of vias.
Aspect 20: The memory device of aspect 19, where the first end of each via of the second plurality of vias is coupled with the first end of the respective via of the first plurality of vias via a respective portion of circuitry.
Aspect 21: The memory device of any of aspects 19 through 20, where the first end of each via of the fourth plurality of vias is coupled with the first end of the respective via of the third plurality of vias via a respective portion of circuitry.
Aspect 22: The memory device of any of aspects 19 through 21, where the first end of each via of the second plurality of vias includes a first metallic pad, and the first end of each via of the third plurality of vias includes a second metallic pad.
Aspect 23: The memory device of any of aspects 19 through 22, where: the first die further includes a first oxide layer, a silicon layer over the first oxide layer, a second oxide layer over the first oxide layer, a circuitry layer over the first oxide layer, and a third oxide layer over the circuitry layer, and the second die further includes a data proximity layer, a fourth oxide layer over the data proximity layer, a second circuitry layer over the fourth oxide layer, a metallic layer over the second circuitry layer, and fifth oxide layer over the metallic layer.
Aspect 24: The memory device of aspect 23, where: the first plurality of vias extend through the first oxide layer, the silicon layer, and the second oxide layer of the first die in a first direction, the second plurality of vias extend through the third oxide layer in the first direction, the third plurality of vias extend through the fifth oxide layer in the first direction, and the fourth plurality of vias extend through the fourth oxide layer and into a portion of the data proximity layer in the first direction.
Aspect 25: The memory device of any of aspects 19 through 24, where the first power delivery network and the second power delivery network form a third power delivery network for the memory device in accordance with the second end of each via of the first plurality of vias being coupled with the second end of a respective via of the third plurality of vias.
Aspect 26: The memory device of any of aspects 19 through 25, where the second die and the first die are coupled together via a hybrid bond.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a first die comprising a first plurality of vias, a first metallic pad, and a second metallic pad, wherein the first plurality of vias, the first metallic pad, and the second metallic pad are associated with a first power delivery network of the first die; and
a second die comprising a second plurality of vias, a third metallic pad, and a first via, wherein the second plurality of vias, the third metallic pad, and the first via are associated with a second power delivery network of the second die,
wherein a first end of each via of the first plurality of vias is coupled with a first end of a respective via of the second plurality of vias, wherein the first metallic pad is coupled with the third metallic pad, and wherein the second metallic pad is coupled with a first end of the first via.

2. The memory device of claim 1, wherein:
a second end of a first via of the second plurality of vias is coupled with a second end of a second via of the second plurality of vias by a first metallic line, and
a second end of a third via of the second plurality of vias is coupled with a second end of a fourth via of the second plurality of vias via a second metallic line.

3. The memory device of claim 2, wherein the first metallic line and the second metallic line comprise copper or aluminum.

4. The memory device of claim 2, wherein the second die further comprises:
a third plurality of vias, wherein a second end of a fifth via of the second plurality of vias is coupled with a first end of a first via of the third plurality of vias via a first portion of circuitry, and wherein a second end of a sixth via of the second plurality of vias is coupled with a first end of a second via of the third plurality of vias via a second portion of the circuitry.

5. The memory device of claim 4, wherein:
the second end of the fifth via is coupled with a fourth metallic pad and the fourth metallic pad is coupled with the first portion of the circuitry, and
the second end of the sixth via is coupled with a sixth metallic pad and the sixth metallic pad is coupled with the second portion of the circuitry.

6. The memory device of claim 1, wherein a second end of the first via is coupled with a fourth metallic pad.

7. The memory device of claim 1, wherein the first die further comprises:
a third plurality of vias, wherein a second end of each via of the first plurality of vias is coupled with a first end of each via of the third plurality of vias via a respective portion of circuitry.

8. The memory device of claim 7, wherein the first end of each via of the third plurality of vias is coupled with a respective fourth metallic pad, and each respective fourth metallic pad is coupled with the respective portion of the circuitry.

9. The memory device of claim 1, wherein:
the first die further comprises a first oxide layer, a silicon layer over the first oxide layer, a second oxide layer over the first oxide layer, a circuitry layer over the first oxide layer, and a third oxide layer over the circuitry layer, and
the second die further comprises a data proximity layer, a fourth oxide layer over the data proximity layer, a second circuitry layer over the fourth oxide layer, and fifth oxide layer over the second circuitry layer.

10. The memory device of claim 9, wherein the second die further comprises a metallic layer between the circuitry layer and the fourth oxide layer.

11. The memory device of claim 9, wherein:
the first plurality of vias extend through the first oxide layer, the silicon layer, and the second oxide layer of the first die in a first direction, and
the first metallic pad and the second metallic pad extend through a portion of the first oxide layer in the first direction.

12. The memory device of claim 9, wherein:
the second plurality of vias and the first via extend through the fifth oxide layer and into a portion of the second circuitry layer in a first direction, and
the third metallic pad extends through a portion of the fifth oxide layer in the first direction.

13. The memory device of claim 1, wherein the first power delivery network and the second power delivery network form a third power delivery network for the memory device in accordance with the first end of each via of the first plurality of vias being coupled with the first end of the respective via of the second plurality of vias, with the first metallic pad being coupled with the third metallic pad, and with the second metallic pad being coupled with the first end of the first via.

14. The memory device of claim 1, wherein the second die and the first die are coupled together via a hybrid bond.

15. A memory device, comprising:
a first die comprising a first plurality of vias and a second plurality of vias, wherein a first end of each via of the second plurality of vias is coupled with a first end of a respective via of the first plurality of vias, and wherein the first plurality of vias and the second plurality of vias are associated with a first power delivery network of the first die; and
a second die comprising a third plurality of vias and a fourth plurality of vias, wherein a first end of each via of the fourth plurality of vias is coupled with a first end of a respective via of the fourth plurality of vias, wherein the third plurality of vias and the fourth plurality of vias are associated with a second power delivery network of the second die,
wherein a second end of each via of the first plurality of vias is coupled with a second end of a respective via of the third plurality of vias.

16. The memory device of claim 15, wherein the first end of each via of the second plurality of vias is coupled with the first end of the respective via of the first plurality of vias via a respective portion of circuitry.

17. The memory device of claim 15, wherein the first end of each via of the fourth plurality of vias is coupled with the first end of the respective via of the third plurality of vias via a respective portion of circuitry.

18. The memory device of claim 15, wherein the first end of each via of the second plurality of vias comprises a first metallic pad, and the first end of each via of the third plurality of vias comprises a second metallic pad.

19. The memory device of claim 15, wherein:
the first die further comprises a first oxide layer, a silicon layer over the first oxide layer, a second oxide layer over the first oxide layer, a circuitry layer over the first oxide layer, and a third oxide layer over the circuitry layer, and
the second die further comprises a data proximity layer, a fourth oxide layer over the data proximity layer, a second circuitry layer over the fourth oxide layer, a metallic layer over the second circuitry layer, and fifth oxide layer over the metallic layer.

20. The memory device of claim 19, wherein:
the first plurality of vias extend through the first oxide layer, the silicon layer, and the second oxide layer of the first die in a first direction,
the second plurality of vias extend through the third oxide layer in the first direction,
the third plurality of vias extend through the fifth oxide layer in the first direction, and
the fourth plurality of vias extend through the fourth oxide layer and into a portion of the data proximity layer in the first direction.

21. The memory device of claim 15, wherein the first power delivery network and the second power delivery network form a third power delivery network for the memory device in accordance with the second end of each via of the first plurality of vias being coupled with the second end of a respective via of the third plurality of vias.

22. The memory device of claim 15, wherein the second die and the first die are coupled together via a hybrid bond.

23. A method for forming a memory device, comprising:
forming a first die over a first substrate, the first die comprising a first plurality of vias, a first metallic pad, and a second metallic pad, wherein the first plurality of vias, the first metallic pad, and the second metallic pad form a portion of a first power delivery network of the first die;
forming a second die over a second substrate, the second die comprising a second plurality of vias, a third metallic pad, and a first via, wherein the second plurality of vias, the third metallic pad, and the first via form a portion of a second power delivery network of the first die; and
bonding the second die with the first die, wherein a first end of each via of the first plurality of vias is bonded with a first end of a respective via of the second plurality of vias, wherein the first metallic pad is bonded with the third metallic pad, and wherein the second metallic pad is bonded with a first end of the first via.

24. The method of claim 23, further comprising:
forming a plurality of first dies including the first die on a first wafer;
forming a plurality of second dies including the second die on a second wafer; and
bonding the first wafer with the second wafer, wherein bonding the second die with the first die is based at least in part on bonding the first wafer with the second wafer.

25. The method of claim 23, wherein the second die and the first die are bonded via a hybrid bond.

26. The method of claim 23, wherein a face of the second die is bonded with a back of the first die.
